(19) United States
(12) Patent Application Publication
(10) Pub. No.: US 2018/0336162 A1
(43) Pub. Date: Nov. 22, 2018

(54) METHOD AND DEVICE FOR RECONSTRUCTING A USEFUL SIGNAL FROM A NOISY ACQUIRED SIGNAL

(71) Applicants: CENTRE NATIONAL D'ETUDES SPATIALES, Paris Cedex (FR); UNIVERSITE DE BOURGOGNE, DIJON (FR)

(72) Inventors: Anthony BOSCARO, DIJON (FR); Sabir JACQUIR, DIJON (FR); Stephane BINCZAK, FLEUREY-SUR-OUCHE (FR); Kevin SANCHEZ, ESCALQUENS (FR); Philippe PERDU, TOULOUSE (FR)

(73) Assignees: CENTRE NATIONAL D'ETUDES SPATIALES, Paris Cedex (FR); UNIVERSITE DE BOURGOGNE, DIJON (FR)

(21) Appl. No.: 16/050,757

(22) Filed: Jul. 31, 2018

Related U.S. Application Data
(63) Continuation of application No. PCT/EP2017/052065, filed on Jan. 31, 2017.

(30) Foreign Application Priority Data
Feb. 1, 2016 (FR) 16/50784

(51) Int. Cl. G06F 17/14; G01R 1/07; G01R 31/311

(52) U.S. Cl. CPC G06F 17/148; G01R 31/311; G01R 1/071

(57) ABSTRACT

The present disclosure relates to a method and a device for reconstructing a useful signal from an acquired signal made up of a plurality of samples representing physical quantities measured. The acquired signal includes the useful signal made noisy by a noise. The method includes decomposing the acquired signal on a predetermined wavelet decomposition base according to a given number of decomposition levels, and obtaining corresponding wavelet coefficients representing the acquired signal. The method further estimates a value representing the standard deviation of the noise from at least one portion of the wavelet coefficients; and implements an iterative method for reconstructing parsimonious signals on the acquired signal with a dictionary built from the wavelet decomposition base. The iterative method has an associated stop criterion that is calculated as a function of the value representing the estimated noise.

### CROSS-REFERENCE TO RELATED APPLICATIONS

This application is a continuation of International Application No. PCT/EP2017/052065, filed on Jan. 31, 2017, which claims priority to and the benefit of FR 16/50784 filed on Feb. 1, 2016. The disclosures of the above applications are incorporated herein by reference.

### FIELD

The present disclosure relates to a method for reconstructing a low-amplitude signal buried in noise, and in particular in the reconstruction of transient signals.

### BACKGROUND

The statements in this section merely provide background information related to the present disclosure and may not constitute prior art.

In electro-optical probing of electronic components, the electronic component, for example a transistor, is subjected to an electromagnetic wave, sent by a laser, i.e. toward a fixed point of the component or by scanning, toward a plurality of points of the component.

A reflected electromagnetic wave is obtained, represented in the form of a temporal signal, where each sample represents a voltage value of the reflected electromagnetic signal. One potential concern, is in analyzing this signal to deduce the condition of the tested electronic component(s).

In particular, the acquired electrical signal is very noisy and cannot be directly exploited. The noise is due to various noise sources, such as thermal, electronic sources, and it has been observed that the amplitude level of the noise is higher than the amplitude level of the useful signal, or, in other words, the signal-to-noise ratio is very low.

To acquire the signal, a treatment is applied to the signal to extract the useful signal so as to characterize the condition of the electronic components being tested. The treatment is a signal processing method allowing reconstructing a useful signal from a noisy signal, where the characteristics of the noise should be known in an accurate manner.

For actual applications, the noise amplitude level is not known in advance. A known signal processing method includes performing several acquisitions, and in performing averages on these acquisitions in order to obtain a signal having a better signal-to-noise ratio. However, in this particular case of electronic components testing, it has been observed that subjecting an electronic component to a laser beam for an extended duration induces a degradation of the operating properties of the electronic component. These and other issues are addressed by the present disclosure.

### SUMMARY

The present disclosure provides a method for reconstructing a useful signal from an acquired signal composed by a plurality of samples representative of measured physical quantities. The acquired signal includes the useful signal noised by a noise. In one form, the method is implemented by a processor of a programmable device. The method includes a decomposition of the acquired signal on a predetermined wavelet decomposition base according to a given number of decomposition levels, and the obtainment of corresponding wavelet coefficients representative of said acquired signal. The method further includes an estimation of a value representative of the standard deviation of said noise from at least one portion of the wavelet coefficients, an implementation of an iterative method for reconstructing parsimonious signals on the acquired signal with a dictionary constructed from the wavelet decomposition base. The iterative method has an associated stopping criterion that is calculated according to the estimated value representative of the noise.

In one aspect, the method of the present disclosure allows reconstructing a useful signal from a noisy acquired signal, without any prior knowledge of the noise level.

In another aspect, the use of a wavelet decomposition allows obtaining a spatio-temporal characterization of the acquired signal, regardless of the underlying characteristics of the useful signal.

The method according to the present disclosure may present one or more of the features hereinbelow, considered independently or according to any technically feasible combination.

In one form, the estimation of a value representative of the standard deviation of said noise includes the estimation of a median value of the absolute values of the amplitude of the considered wavelet coefficients.

In another form, when the noise is a white noise characterized by a centered Gaussian distribution, independently distributed for each sample of the acquired signal, the estimation of a value representative of the standard deviation of said white noise includes the weighting of said median value by a quantile of a centered Gaussian distribution with a variance equal to one.

In yet another form, the stopping criterion is calculated from an estimate of the norm L2 of said white noise.

In one form, the method includes a step of automatic determination of the number of wavelet decomposition levels to perform.

In another form, the method includes a step of selecting a mother wavelet allowing defining the wavelet decomposition base to use.

In yet another form, the acquired signal is representative of an electrical signal obtained from an opto-electronic signal reflected by an electronic component to be tested.

According to another aspect, the present disclosure concerns a device for reconstructing a useful signal from an acquired signal composed by a plurality of samples representative of measured physical quantities. The acquired signal includes the useful signal noised by a noise, implemented by a processor of a programmable device. This device includes a processor that is configured to include modules adapted to implement: a decomposition of the acquired signal on a predetermined wavelet decomposition base according to a given number of decomposition levels, and the obtainment of corresponding wavelet coefficients representative of said acquired signal; an estimation of a value representative of the standard deviation of said noise from at least one portion of the wavelet coefficients; an implementation of an iterative method for reconstructing parsimonious signals on the acquired signal with a dictionary constructed from the wavelet decomposition base, where said iterative method has an associated stopping criterion that is calculated according to the estimated value representative of the noise.

According to another aspect, the present disclosure concerns a computer program including software instructions which, when implemented by a programmable device, implement a method for reconstructing a useful signal from an acquired signal as briefly described hereinabove.

According to another aspect, the present disclosure concerns a method for processing a plurality of digital signals. Each digital signal is composed by a plurality of samples representative of measured physical quantities, including an acquisition of said plurality of digital signals. Each acquired digital signal corresponds to a sample of a bi-dimensional digital image, and includes a useful signal noised by a noise. The method for processing includes an implementation of a method, as briefly described hereinabove, for reconstructing the useful signal corresponding to each acquired signal.

According to one form, the processing method includes a step of acquiring a digital signal for a current pixel of the bi-dimensional digital image, and a step of selecting a next pixel to process as a current pixel.

According to one form, after reconstruction of a useful signal corresponding to each acquired signal, the method includes, for at least one portion of the samples of said bi-dimensional digital image, a step of calculating a dominant frequency from the useful signal associated to the sample, so as to form a frequency mapping associated to said bi-dimensional image.

According to one form, each acquired digital signal is representative of an electrical signal obtained from an opto-electonic signal reflected by an electronic component to be tested, and the processing method enables an analysis of said component

According to another aspect, the present disclosure concerns a device for processing a plurality of digital signals, including an acquisition of said plurality of digital signals. Each digital signal is composed by a plurality of samples representative of measured physical quantities. Each acquired digital signal corresponds to a sample of a bi-dimensional digital image, and includes a useful signal noised by a noise. The device for processing includes a device for reconstructing the useful signal from the acquired signal composed by a plurality of samples representative of measured physical quantities as briefly described hereinabove.

According to another aspect, the present disclosure concerns a computer program including software instructions which, when implemented by a programmable device, implement a method for processing a plurality of digital signals as briefly described hereinabove.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 schematically illustrates an electro-optical system for analyzing an electronic component in which the present disclosure finds application;

FIG. 2 illustrates an example of an acquired signal and an estimate of the corresponding useful signal according to the present disclosure;

FIG. 3 is a flowchart of the main steps of a method for reconstructing a useful signal in accordance with the teachings of the present disclosure;

FIG. 4 is a diagram representing the functional blocks of a programmable device in accordance with the teachings of the present disclosure;

FIG. 5 is a flowchart of the main steps of a method for processing signals implementing a method for reconstructing useful signals in accordance with the teachings of the present disclosure; and

FIG. 6 schematically illustrates a bi-dimensional image corresponding to an area of interest and a corresponding signal before reconstruction in accordance with the teachings of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

The present disclosure will be described hereinafter in the context of an application to the electro-optical probing of an electronic component.

Nonetheless, the present disclosure is applicable to other fields, including fields involving an analysis of a highly-noisy acquired signal, containing a useful signal having low amplitude in comparison with the amplitude of the noise, the acquired signal being transient.

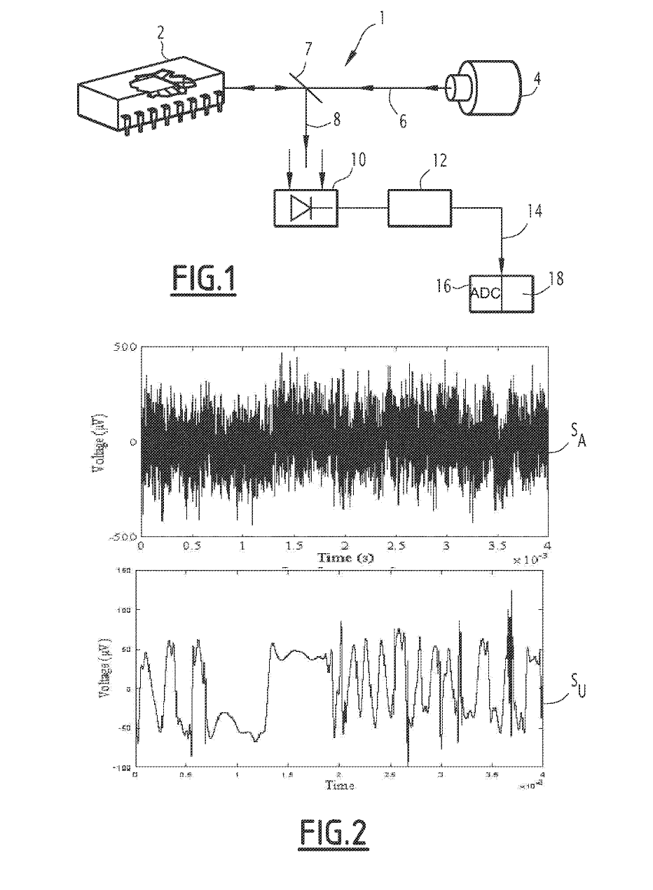

FIG. 1 schematically illustrates an electro-optical system for analyzing an electronic component, also called “voltage laser probing” system.

The system 1 includes an electronic component 2 to be tested, for example a transistor.

A laser source 4 emits an electro-optical signal 6 in the direction of a predetermined fixed point of the component 2 to be tested.

Alternatively, the laser source 4 is adapted to perform a scanning, and therefore to emit an electro-optical signal in a beam of directions, each direction corresponding to a spatial point of a component or electronic circuit to be tested.

A laser excitation over a predetermined duration is applied at each targeted point, allowing acquiring, via a reflective element 7, an electro-optical signal 8 reflected by the electronic component 2 to be tested, or by each spatial point determined by the beam of directions in the case of a scanning laser source, over a given time duration.

The reflected electro-optical signal 8 is sent toward a circuit 10 including a photodiode and a preamplifier to transform this electro-optical signal into an electrical signal, and is then transmitted to an amplifier 12.

An acquired electrical signal 14, which is the signal to be processed, is obtained at the output of the amplifier 12.

For a spatial point reached by an electro-optical signal 6 emitted by the laser source, an electrical signal 14 is obtained which is supplied to a programmable processing device 18, after an analog-to-digital conversion by a converter 16.

In one form, the modules 16 and 18 are combined within a digital signal processor or DSP.

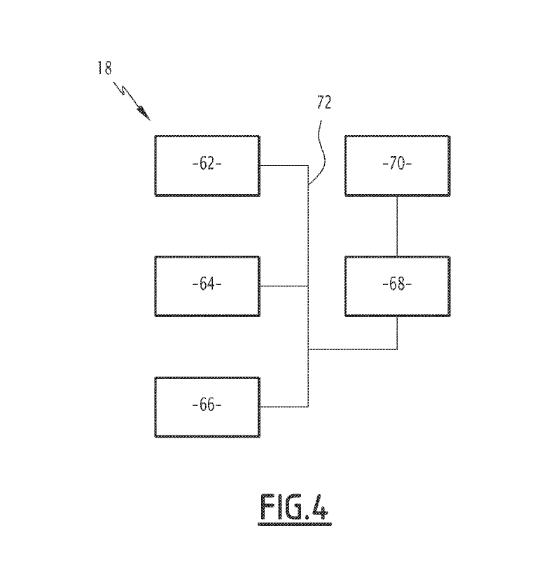

The programmable processing device 18 comprises a processor, capable of executing program code instructions to perform calculations when the programmable device is turned on. It also comprises at least one memory allowing memorizing parameters, variables and code instructions. An example of a programmable processing device will be described hereinafter with reference to FIG. 4.

FIG. 2 illustrates an acquired electrical signal S_{A}, where each point thereof represents an electrical voltage value at a given time point.

As it may be observed, such an acquired signal is particularly noisy, and consequently it cannot be exploited as it stands.

The acquired electrical signal S_{A} is formed by the addition of a useful signal, which is representative of the response of the tested electronic component to the emitted electro-optical signal 6, and of a high-amplitude noise.

The present disclosure provides a method to reconstruct the useful signal S_{U} from the acquired signal S_{A}. FIG. 2 illustrates the signal S_{U} extracted from the signal S_{A} by the application of the useful signal reconstruction method of the present disclosure in one form.

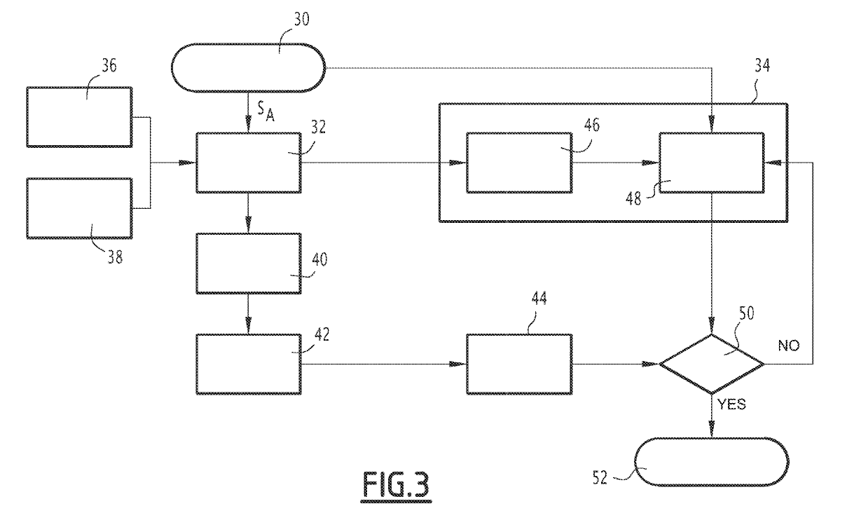

FIG. 3 is a flowchart of the main steps of a method for reconstructing a useful signal from a noisy signal according to a first form of the present disclosure.

At a first step 30 of acquiring the signal, a signal S_{A} is acquired and digitized.

In one form, the acquired signal S_{A} is a temporal signal including samples representative of the measured voltage values.

As explained hereinabove, the acquired signal S_{A} includes a useful signal buried in high-amplitude noise.

It is supplied at the input of a step 32 of applying a decomposition of the acquired signal on a predetermined wavelet decomposition base, as well as at the input of a step 34 of applying an iterative method of reconstructing parsimonious signals, which technology is also known as «compressive sensing», which aims at reconstituting a signal from a small number of non-zero representative samples in a predetermined decomposition base.

Step 32 of applying a decomposition of the acquired signal on a wavelet decomposition base includes using an initial wavelet or mother wavelet, supplied by a step 36, and in applying the wavelet decomposition over a number L of decomposition levels, supplied by a step 38. These two parameters, namely the shape of the mother wavelet and the number of decomposition levels, enable full definition of the wavelet decomposition base to use.

In one form, steps 36 and 38 consist in reading these parameters in a memory of the device adapted to implement the present disclosure.

The values of these parameters may be supplied by a user via a human-machine interface of the device implementing the method of the present disclosure.

In one form, the mother wavelet is the wavelet called Symmlet.

Alternatively, the Daubechies, Haar, Meyer or Coiflet wavelets are used.

An increased number of decomposition levels Lₘₐₓ that can be applied depends on the number of samples of the acquired signal S_{A} to decompose.

For example, if the signal S_{A} includes 512 samples, the increased number of decomposition levels is Lₘₐₓ=9. More generally, for an n-sample signal, Lₘₐₓ=log₂(n).

In practice, L may be chosen smaller than Lₘₐₓ.

In one aspect, the number of decomposition levels L is chosen between 2 and Lₘₐₓ, at an intermediate value so as to obtain a good tradeoff between the consideration of noise and a possible loss of information.

Alternatively, the number L of decomposition levels is automatically calculated at step 38. In this case, steps 32 and 38 are iterated by increasing the number of decomposition levels until a criterion is met, for example an entropy criterion calculated on the coefficients of the decomposition.

For example, the method disclosed in the article “Entropy-based method of choosing the decomposition level in wavelet threshold denoising” of Y. F. Sang et al, published in 2010 in Entropy journal, vol. 12, No. 6, pages 1499-1513.

After the application 32 of the decomposition on the chosen wavelet base, a set of representative coefficients or wavelet coefficients of the acquired signal on this decomposition base is obtained.

The representation of the acquired signal S_{A} is said parsimonious if several obtained coefficients are equal to zero or have an absolute value or magnitude close to 0, that is to say lower than a predetermined threshold ε.

A subset of the calculated coefficients is selected at a coefficients selection step 40.

For this step of choosing the coefficients, the selection is made for example via a sub-sampling matrix defined beforehand by the user via the human-machine interface of the device implementing the method of the present disclosure. The size of this matrix is [m, n] with m being the number of chosen coefficients, and n being the size of the acquired signal, when it consist of a one-dimensional signal as illustrated in FIG. 2. This matrix serves to sub-sample in the new base, which is equivalent to a compression.

Consider [symbol] an n-sample signal, which is the initial acquired signal and [symbol] the matrix in which the signal x has the best parsimonious representation, for example the discrete wavelet base. Consider [symbol] the best parsimonious representation of x in the base [symbol] .

Then we have: x=ψ·S

Note ϕ [symbol] a sub-sampling matrix allowing selecting m observations organized into a vector y with m<<n.

We obtain: y=ϕ·x=ϕ·ψ·S

The sub-sampling matrix ϕ is a random matrix with a restricted isometry property or RIP.

In particular, the sub-Gaussian random matrices, whose elements are generated through a pseudo-random drawing according to a Gaussian law, and restricted to an absolute value comprised between 0 and 1, meet the RIP property.

In one form, a 5000×10000 sized sub-Gaussian random sub-sampling matrix is generated for a 10000-sample signal.

In another form, half the coefficients of a decomposition level Iᵢ are selected.

Advantageously, the sub-sampling step 40 can be assimilated to a compression step, the number of coefficients representative of the signal being greatly reduced. The use of a parsimonious representation allows considerably reducing the processing time of the signals.

At a step 42, an estimation of a value representative of the standard deviation of the noise present in the acquired signal is implemented.

By assumption, the observed noise is considered to be a white noise, identically and independently distributed over each sample of the observed signal.

In one form, corresponding to the case where the observed noise results from a sum of physical phenomena, the noise has a centered Gaussian distribution, and it is entirely characterized by the value of the variance or of the standard deviation of the distribution.

In the considered application, the variance σ² of the Gaussian white noise is unknown, but is estimated from the wavelet decomposition coefficients selected at the sub-sampling step 40.

According to one form, at step 42, the mean absolute deviation or MAD of a portion of the wavelet decomposition coefficients, obtained after decomposition of the acquired signal, is estimated.

In one aspect, consider [symbol] the wavelet decomposition coefficients of the first decomposition level, mainly composed by noise, and calculate the median value of the absolute value of the coefficients by:

MAD((wⱼ)ₗ_{ᵢ})=Med((|wⱼ|)ₗ_{ᵢ}) (Eq 1)

In one form, the variance of the Gaussian white noise present in the signal is estimated by the following estimator:

$${σ}^{2} = {( \frac{MAD ( {( {w}_{j} )}_{{l}_{i}} )}{0.64745} )}^{2} \qquad ( Eq 2 )$$

The value 0.6745 being the 0.75-quantile of the centered Gaussian distribution with a variance equal to 1.

The estimator provided by the formula (Eq 2) is particularly suited for the case of a one-dimensional acquired signal, as illustrated in FIG. 2, with an additional centered Gaussian white noise. In practice, it has been observed that such a noise is for example present in the case of the electro-optical probing of electronic components.

The noise estimation step 42 is followed by a step 44 of estimating the norm L₂ of the noise present in the acquired signal S_{A}.

In the above-described form, the norm L₂ of the noise is equal to the estimated standard deviation σ.

The estimated norm L₂ is subsequently used as a stopping criterion of the iterative method for reconstructing parsimonious signals implemented at step 34.

In one form, the used compressive acquisition method is a method called an orthogonal matching pursuit or OMP method.

This method comprises a first substep 46 of selecting a dictionary of base functions, among the wavelet decomposition base previously obtained at step 36. Afterwards, the OMP algorithm is implemented at step 48.

Step 50 implements an automatic stopping criterion of the iterative reconstruction method, this stopping criterion being calculated from the norm L₂ of the noise previously estimated at step 44. In the OMP criterion, as soon as the norm of the residual of said algorithm becomes greater than or equal to the norm of the previously-estimated noise, the iteration is stopped.

If the stopping criterion is not met, step 50 is followed by step 48.

If the stopping criterion is met, the useful signal S_{U} is obtained at step 52.

The above-described method is implemented by a programmable processing device, for example a computer, as schematized in FIG. 4.

A programmable device 18 capable of implementing the present disclosure, typically a computer, comprises a central processing unit 68, or CPU, capable of executing computer program instructions when the device 18 is turned on. The device 18 also includes means for storing information 70, for example registers or memories, capable of storing executable code instructions enabling the implementation of programs including code instructions capable of implementing the methods according to the present disclosure.

Optionally, the programmable device 18 comprises a screen 62 and an element 64 for inputting the commands of an operator, for example a keyboard, optionally an additional pointing device 66, such as a mouse, allowing selecting graphical elements displayed on the screen 62.

The various functional blocks 62 to 70 of the device 18 described hereinabove are connected via a communication bus 72.

In a one form, the programmable device 18 is made in the form of programmable logic components, such as one or several FPGA(s) (Field-Programmable Gate Array), or still in the form of ASIC-type (Application-Specific Integrated Circuit) dedicated integrated circuits.

FIG. 5 is a flowchart of the main steps of a method for processing signals implementing a reconstruction of a useful signal from a noisy signal according to one form of the present disclosure.

Such a processing method is also implemented by a programmable device as described hereinabove with reference to FIG. 4.

In this form, spatio-temporal signals, also called 2D+t signals, are processed.

A bi-dimensional image of temporal signals is formed. To each sample of the 2D image corresponds a predetermined fixed point of the component 2 to be tested.

Thus, an entire area of the component to be tested is analyzed.

In a first signal acquisition phase 80, the laser beam is successively pointed on various points of the component to be tested so as to acquire the corresponding signals.

The phase 80 includes a first substep 82 of acquiring a digital signal for a current pixel.

The laser is focused during a duration to be determined on the point of the component to be tested corresponding to the current pixel.

In this form, the laser is maintained as long as the signal-to-noise ratio is lower than a predetermined value, the noise being estimated on the acquired signal by application of a wavelet transformation as described hereinabove.

In one form, a value representative of the standard deviation of the noise is estimated from the first wavelet coefficients as described hereinabove.

A substep 84 implements the check-up of the value of the signal-to-noise ratio for the acquired signal associated to the current pixel.

When the signal-to-noise ratio for the current acquired signal reaches the predetermined level, the substep 84 is followed by a substep 86 of selecting a next pixel to process as a current pixel.

For each current pixel, the acquired signal has the same number of samples.

The selection of a next pixel to process may be performed according to a systematic routing order of the bi-dimensional image to fill, for example according to a usual rows-columns routing, or by a pseudo-random selection of a next pixel to process.

According to another form, only the locations where transistors, for example, lie are tested, and therefore only a sub-portion of the bi-dimensional image is formed corresponding to an area of interest for the analysis.

The substep 86 is followed by the previously-described substep 82, until the complete acquisition of the signals associated to all the pixels of the bi-dimensional image to fill.

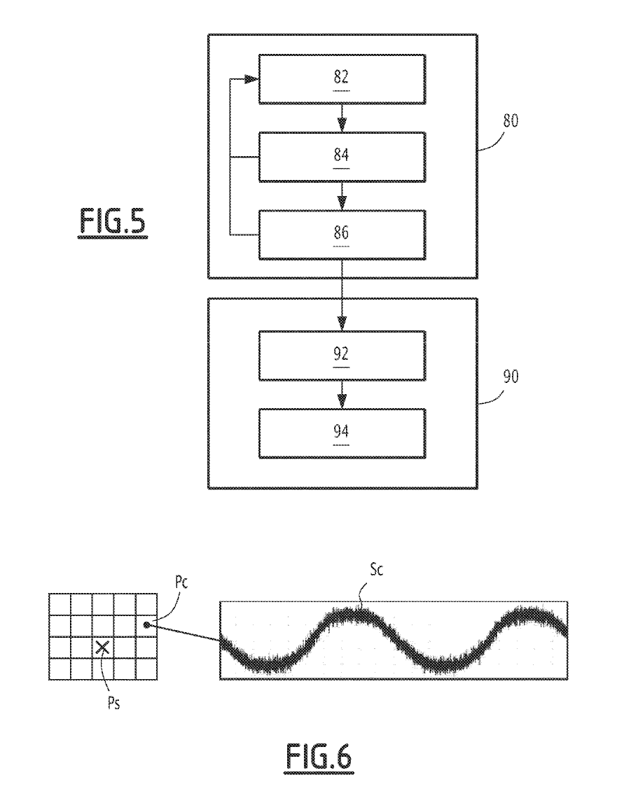

FIG. 6 schematically illustrates a bi-dimensional image and an acquired signal Sc associated to a current pixel Pc, as well as a next pixel Ps chosen in a pseudo-random manner.

After the acquisition 80, a processing step 90 is implemented.

The acquired signals for each of the pixels are reconstructed according to the above-described reconstruction method at a substep 92.

Afterwards, at a substep 94, a discrete Fourier transformation is applied to each of the signals acquired and simplified by reconstruction, a dominant frequency is thereby deduced for each of the pixels.

A frequency mapping of the analyzed area of interest is then obtained.

Alternatively, other additional treatments may be applied for each of the acquired signals, allowing obtaining a mapping of the analyzed area of interest for another criterion.

Advantageously, the proposed method allows estimating the de-noised signal from a greatly reduced number of samples of the initial acquired signal, and consequently improving the calculations to be performed. In addition, the used samples originating from the same signal temporal acquisition; the acquisition time of the signals being greatly reduced, and consequently the total processing time of the signals is also greatly reduced.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method for reconstructing a useful signal from an acquired signal composed by a plurality of samples representative of measured physical quantities, the acquired signal including the useful signal noised by a noise, implemented by a processor of a programmable device, the method comprising:
decomposing the acquired signal on a predetermined wavelet decomposition base according to a given number of decomposition levels, and obtaining corresponding wavelet coefficients representative of the acquired signal;
estimating a value representative of the standard deviation of the noise from at least one portion of the wavelet coefficients; and
implementing an iterative method for reconstructing parsimonious signals on the acquired signal, with a dictionary constructed from the wavelet decomposition base, wherein the iterative method has an associated stopping criterion, and the stopping criterion is calculated according to the estimated value representative of the noise.

2. The reconstruction method according to claim 1, wherein the estimation of the value representative of the standard deviation of the noise further comprises estimating a median value of the absolute values of the amplitude of the considered wavelet coefficients.

3. The reconstruction method according to claim 2, wherein the noise is a white noise characterized by a centered Gaussian distribution, independently distributed for each sample of the acquired signal, and the estimation of the value representative of the standard deviation of the white noise further comprises weighting of the median value by a quantile of a centered Gaussian distribution with a variance equal to one.

4. The reconstruction method according claim 1, wherein the stopping criterion is calculated from an estimate of the norm L2 of the noise.

5. The reconstruction method according to claim 1 further comprising automatically determining the number of wavelet decomposition levels to perform.

6. The reconstruction method according to claim 1 further comprising selecting a mother wavelet allowing defining the wavelet decomposition base to use.

7. The reconstruction method according to claim 1, wherein the acquired signal is representative of an electrical signal obtained from an opto-electronic signal reflected by an electronic component to be tested.

8. A processing method for a plurality of digital signals, the processing method comprising:
acquiring the plurality of digital signals, wherein each digital signal is composed by a plurality of samples representative of measured physical quantities, each acquired digital signal corresponding to a sample of a bi-dimensional digital image and includes a useful signal noised by a noise; and
the method according to claim 1 for reconstructing the useful signal from the acquired digital signal.

9. The processing method according to claim 8 further comprising acquiring a digital signal for a current pixel of the bi-dimensional digital image, and selecting a next pixel to process as a current pixel.

10. The processing method according to claim 9 further comprising, after reconstruction of a useful signal corresponding to each acquired signal, calculating a dominant frequency from the useful signal associated to the sample to form a frequency mapping associated to the bi-dimensional image for at least one portion of the samples of the bi-dimensional digital image.

11. The processing method according to claim 8, wherein each acquired digital signal is representative of an electrical signal obtained from an opto-electonic signal reflected by an electronic component to be tested.

12. A device for reconstructing a useful signal from an acquired signal including a plurality of samples representative of measured physical quantities, the acquired signal including the useful signal noised by a noise, the device comprising:
one or more processors configured to:
decompose the acquired signal on a predetermined wavelet decomposition base according to a given number of decomposition levels, and to obtain corresponding wavelet coefficients representative of the acquired signal,
estimate a value representative of the standard deviation of the noise from at least one portion of the wavelet coefficients, and
implement an iterative method for reconstructing parsimonious signals on the acquired signal with a dictionary constructed from the wavelet decomposition base, wherein the iterative method has an associated stopping criterion, the stopping criterion is calculated according to the estimated value representative of the noise.

13. A computer-readable medium having computer-executable instructions for performing the method of claim 1.

14. A device for processing a plurality of digital signals comprising:
the device for reconstructing the useful signal according to claim 12, wherein the acquired signal is a plurality of digital signals, each digital signal includes a plurality of samples representative of measured physical quantities, each acquired digital signal corresponds to a sample of a bi-dimensional digital image.

15. A computer-readable medium having computer-executable instructions for performing the method of claim 8.
